(19) United States
(12) Patent Application Publication
(10) Pub. No.: US 2004/0173377 A1
(43) Pub. Date: Sep. 9, 2004

(54) Carrier foil for electronic components, for laminating inside chip cards

(76) Inventor: Carsten Senge, Kiel (DE)

Correspondence Address: FOLEY AND LARDNER, SUITE 500, 3000 K STREET NW, WASHINGTON, DC, 20007, US

(21) Appl. No.: 10/474,357

(22) PCT Filed: Feb. 26, 2002
(86) PCT No.: PCT/DE02/00686

(30) Foreign Application Priority Data
Apr. 10, 2001 (DE) 10 117 994.4

(51) Int. Cl. H05K 1/16

(52) U.S. Cl. 174/260

(57) ABSTRACT

The invention relates to a carrier foil for electronic components, for laminating inside chip cards comprising at least one strip conductor (2) arranged on a carrier foil body and provided with connection regions (3, 4, 5, 6) consisting of a conductive material and used to connect to other electronic components or connecting bridges. Said connection regions (3, 4, 5, 6) comprise a plurality of interconnected partial surfaces (7) consisting of said conductive material, and free surfaces (8) which are arranged between said partial surfaces and which are not coated with said conductive material. The inventive embodiment enables deformation resulting from the difference between the expansion capacity of the carrier foil material and that of the connection region material to be reduced and simultaneously the adhesion forces between a plastic cover and the actual carrier foil material to be increased in the connection regions. The invention also relates to a chip card comprising the inventive carrier foil and a method for producing said carrier foil.

The invention relates to a carrier foil for electronic components, for laminating inside chip cards, with at least one strip conductor arranged on a carrier foil body and provided with connection regions consisting of conductive material for connection to further electronic components or connecting bridges. The invention also relates to a chip card with a chip card body, at least one electronic component (chip) and a carrier foil for electronic components which is laminated into the chip card body and has at least one strip conductor arranged on a carrier foil body and provided with connection regions consisting of conductive material for connection to the electronic component. In addition, the invention relates to a method for producing the carrier foil according to the invention. In the case of an advantageous use, the carrier foil mentioned can be used in particular as an antenna carrier foil for contactless chip cards, the strip conductor in this case being formed as an antenna coil.

In the case of chip cards, which are already extensively used for various applications in the prior art, such as for example as phone cards, access authorization cards, cash cards or the like, a distinction is drawn in principle between three different embodiments with regard to the data exchange between the electronic component (chip) arranged on the chip card and further components that may be provided, such as displays or buttons with external readers. In the case of very many chip cards, the data exchange referred to with external readers takes place via contact areas which are located on the outside of the chip card. A further possibility for data exchange takes place with the aid of readers which operate with contactless data transmission. For this purpose, the chip card has in its chip card body a corresponding component for contactless data transmission, for example an antenna in the form of an antenna coil. For such an antenna coil, a comparatively large area is required, with the result that accommodation in the chip module is possible only with great difficulties. Therefore, antenna coils are accommodated separately in the chip card body, the production operation providing for the antenna coil to be arranged together with the chip or separately on a special antenna carrier foil, which is produced in a separate operation and subsequently implanted in the chip card body by means of a laminating process. For this purpose, the carrier foil is covered on its upper side and underside with one or more layers of plastic and joined together with the chip card body by means of pressure and heat.

As a third variant with respect to the data exchange between the chip card and readers, there are chip cards which have both contact areas for with-contact data exchange and antenna coils for contactless data exchange.

The antenna arranged in the interior of the chip card on the carrier foil has for the electrical connection to further electronic components, for example a chip module or display devices, connection regions which consist of conductive material and are connected to the strip conductor or conductors, which form the actual antenna coil and further electrical connections between the components. These connection regions are usually configured as rectangular solid areas, like the strip conductors preferably consist of a layer of copper and usually have side dimensions of about 0.5×0.5 mm or greater. In addition, the connection regions may, however, also have a round or oval form, the area dimension lying in the range of 0.25 mm² or greater.

In the production of the carrier foil with strip conductors and connection regions there is in the prior art the problem that the different thermal expansion of the carrier foil material and the conductive material of the connection regions causes an effect similar to the bimetal effect to occur during heating. This means that the carrier foil or the material of the connection areas warps during the laminating operation for producing the chip card body. These warpages are disadvantageous to the extent that the regions of the connection areas are often clearly visible to the naked eye on the surface of the chip card when lamination has been completed, since the warpage does not fully recede after cooling.

In addition, it has proven to be disadvantageous that the forces of adhesion between the conductive material of the connection areas and the layer of plastic arranged over the carrier foil as part of the laminating process are extremely low, which can under some circumstances significantly impair the bond between the connection areas and the layer of plastic within the card body.

On the basis of the disadvantages referred to that are known from the prior art, the object according to the invention is to overcome them both with respect to improving the final quality of the chip cards and with regard to improving the holding forces between the connection regions of the carrier foil and the layer of plastic surrounding them.

These objects are achieved by a carrier foil and a chip card with a corresponding carrier foil according to the independent patent claims. The carrier foil according to the invention can be produced by a method according to the independent method claim.

The basic idea of the invention is that the connection regions have a plurality of interconnected subareas consisting of the conductive material and free areas, which are arranged between these subareas and are not coated with the conductive material. The connection regions consequently no longer comprise a solid area, as known from the prior art, but are provided with a plurality of apertures, one effect being that the expansion of the connection regions as a result of heat being supplied is considerably reduced. In addition, the way in which the connection regions are formed according to the invention offers the possibility for the layer of plastic covering the carrier foil that the regions of the connection regions that are not coated with the conductive material can bond much better with the latter.

Special forms of the carrier foil according to the invention are provided by the subclaims related to the relevant main claim. A particularly advantageous and low-cost form provides here that the interconnected subareas are formed as crossing strip conductors with rectangular free areas lying between them.

In addition, it has been found to be advantageous in particular in the case of the connection regions intended for the connection to chip modules to form these connection regions as rectangular subareas consisting of conductive material and adjoining free areas enclosed by a strip conductor connected to this subarea. This allows the adhesion of the covering layer of plastic to be increased significantly, in particular in the edge region of the subareas consisting of conductive material, by the generous interruptions in relation to the surface area.

The invention is used primarily in the case of Dual Interface Cards (DIC), but it goes without saying that is is not restricted to this application. The subject matter of the invention is explained in more detail below on the basis of the accompanying drawings, in which:

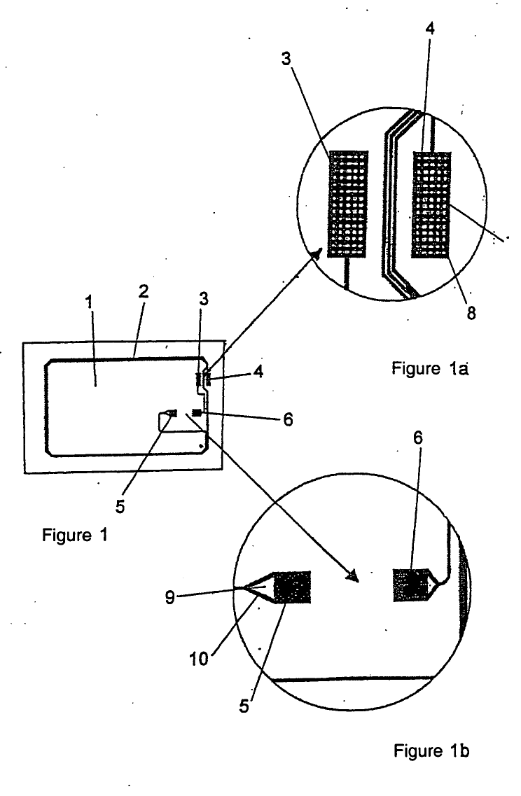

FIG. 1 shows the plan view of a carrier foil according to the invention with an antenna coil arranged on it,

FIG. 1a shows an enlarged representation of the carrier foil from FIG. 1 in the region of connection regions intended for a connecting bridge, and

FIG. 1b shows an enlarged representation of the carrier foil from FIG. 1 in the region of connection regions intended for the connection to a chip module.

The carrier foil represented in FIG. 1 in a plan view comprises a carrier foil body 1 of plastic, on which one or more strip conductors 2 are arranged substantially in a ring-shaped manner as an antenna for contactless data transmission. Arranged in a subregion of the strip conductor ring on either side of the strip conductor 2 there is a connection region 3 and 4, respectively. The connection regions 3, 4 are formed in a substantially rectangular manner with respect to their base area and serve for producing a so-called connecting bridge between the connection regions, the connecting bridge establishing electrical connection between the connection regions 3, 4, without at the same time connecting the strip conductor or conductors located between the connection regions. For this purpose, the connecting bridge is preferably configured as a two-part web, a non-conducting insulating layer being arranged on the strip conductor 2 between the connection regions 3, 4 and after that a bridge of conductive paste being placed on this insulating layer in a first operation during production.

It can also be seen from FIG. 1 that the carrier foil has two further connection regions 5, 6, which serve for the connection of an electronic component which is not represented here in any more detail, for example the chip module of a chip card, into which the antenna carrier foil is laminated.

As FIG. 1 reveals, the connection regions 3 to 6 referred to have a much larger area extent than the associated strip conductors arranged on the antenna carrier foil. Since the coefficient of expansion between the connection areas/strip conductor material, which is usually copper, and the material of the carrier foil differs, when the carrier foil is laminated into a chip card body there is the risk, on account of the supply of heat necessary here, that undulations occur in the region of the connection areas 3 to 6 and are still evident as such in the finished chip card body. To overcome this, the connection areas 3, 4 referred to are formed according to the invention in such a way that they have a plurality of interconnected subareas 7 consisting of the conductive material and free areas 8, which are arranged between these subareas and are not coated with the conductive material. The specific form is revealed in particular by the enlarged representation of a detail of FIG. 1a. In the exemplary embodiment represented, the subareas 7 together with the areas 8 form a lattice design, the interconnected subareas 7 being formed as crossing strip conductors with rectangular free areas 8 lying between them. Of course, it is also conceivable to provide the free regions 8 lying between the interconnected subareas 8 with a circular outline. What is essential about the form according to the invention is that, while there continues to be a base area of approximately the same size as in the case of connection regions of a conventional type, there is no longer a continuous area of conductive material, which on the one hand allows the covering layer of plastic to have a better bond with the carrier foil body 1 at the free areas and at the same time considerably reduces the effect of the different thermal expansion (for example bending of the chip card) of the connection regions 3 and 4 and of the carrier foil, in particular during the laminating process.

Another possible way of forming the subject matter of the invention is represented in FIG. 1b. In the case of the connection regions 5, 6 represented here, a certain size of the connection region is necessary on account of technical boundary conditions for the connection of the chip modules intended here. In order to increase the adhesion between the material of the connection regions and the covering plastic in this region as well, the connection regions 5, 6 likewise have free areas 9, which are not coated with the conductive material and are enclosed by strip conductors 10, which in turn are connected to the strip conductors 2 belonging to the coil ring. By being formed in this way, an increase in the adhesion is also obtained in the case of the connection regions 5, 6, to improve the card structure of the chip cards provided with the antenna coils according to the invention.

### List of Designations

1. carrier foil body

2. strip conductor

3. connection region

4. connection region

5. connection region

6. connection region

7. subarea

8. area

9. area

10. strip conductor

1. A carrier foil for electronic components, for laminating inside chip cards, with at least one strip conductor (2) arranged on a carrier foil body (1) and provided with connection regions (3, 4, 5, 6) consisting of conductive material for connection to further electronic components, characterized in that the connection regions (3, 4, 5, 6) have a plurality of interconnected subareas (7) consisting of the conductive material and free areas (8, 9), which are arranged between these subareas (7) and are not coated with the conductive material.

2. The carrier foil as claimed in claim 1, characterized in that the strip conductor on the carrier foil is formed as an antenna coil.

3. The carrier foil as claimed in claim 1 or 2, characterized in that the interconnected subareas (7) are formed as crossing strip conductors with rectangular free areas (8) lying between them.

4. The carrier foil as claimed in claim 3, characterized in that the free areas (8) have a substantially circular outline.

5. The carrier foil as claimed in one of claims 1 to 4, characterized in that the conductive material is copper.

6. The carrier foil as claimed in one of claims 1 to 5, characterized in that the connection regions (3, 4, 5, 6) have subareas (7) consisting of conductive material and adjoining free areas (9) enclosed by a strip conductor connected to this subarea (7).

7. The carrier foil as claimed in claim 6, characterized in that the enclosed free area (9) has a substantially triangular outline.

8. A chip card with a chip card body, at least one electronic component (chip) and a carrier foil for further electronic components which is laminated into the chip card body and has at least one strip conductor (2) arranged on a carrier foil body and provided with connection regions (3, 4, 5, 6) consisting of conductive material for connection to the electronic component or components, characterized in that the connection regions (3, 4, 5, 6) have a plurality of interconnected subareas (7) consisting of the conductive material and free areas (8, 9), which are arranged between these subareas and are not coated with the conductive material.

9. A method for producing a carrier foil for electronic components, for laminating inside a chip card, in which with the carrier foil has a carrier foil body (1) with at least one strip conductor (2) arranged on it and provided with connection regions (3, 4, 5, 6) consisting of conductive material for connection to an electronic component, characterized in that the connection regions (3, 4, 5, 6) are provided with a plurality of interconnected subareas (7) consisting of the conductive material and free areas (8, 9), which are arranged between these subareas and are not coated with the conductive material.

10. The method as claimed in claim 9, characterized in that the interconnected subareas (7) are formed as crossing strip conductors with preferably rectangular free areas (8) lying between them.

11. The method as claimed in claim 9, characterized in that the connection regions are formed as preferably rectangular subareas (7), consisting of conductive material, and as adjacent free areas (8), surrounded by a strip conductor connected to this subarea.

12. The method as claimed in claim 10, characterized in that the outline of the enclosed free area (9) is formed in a substantially triangular manner.
